(19) United States
(12) Patent Application Publication
(10) Pub. No.: US 2025/0228076 A1
(43) Pub. Date: Jul. 10, 2025

(54) Display Device

(71) Applicant: LG Display Co., Ltd., Seoul (KR)

(72) Inventors: HeeJung Yang, Paju-si (KR); YoungWook Lee, Paju-si (KR); Hoseung Lee, Paju-si (KR)

(21) Appl. No.: 19/000,924

(22) Filed: Dec. 24, 2024

(30) Foreign Application Priority Data
Jan. 5, 2024 (KR) 10-2024-0002104

(51) Int. Cl. H10K 59/122; H10K 59/124; H10K 59/80

(52) U.S. Cl. CPC H10K 59/122; H10K 59/124; H10K 59/80515

(57) ABSTRACT

A display device is disclosed that includes a substrate on which a plurality of subpixels are disposed, each of the plurality of subpixels including a plurality of light emitting areas, a first planarization layer disposed over the substrate, a first pixel electrode disposed on the first planarization layer, a second planarization layer disposed on the first pixel electrode and including at least one opened portion exposing a portion of the upper surface of the first pixel electrode, a second pixel electrode disposed on the second planarization layer, a bank disposed on a portion of the upper surface of the second pixel electrode and including an opening in each of the plurality of subpixels, an emission layer disposed in the opening, and a common electrode disposed on the emission layer, and eliminates or reduces display artifacts such as stained image presenting and the like and improving light emission efficiency.

### CROSS-REFERENCE TO RELATED APPLICATION

This application claims the priority benefit of Republic of Korea Patent Application No. 10-2024-0002104 filed on Jan. 5, 2024, which is hereby incorporated by reference in its entirety.

### TECHNICAL FIELD

The present disclosure relates to electronic devices, and more specifically, to display devices.

### BACKGROUND

Displays capable of presenting information and images on a screen are widely used in a variety of electronic device or systems, and are becoming increasingly important as a core technology in today's society for presenting various information to users. To meet various needs, various types of displays, such as liquid crystal displays (LCD), organic light emitting displays (OLED), micro light emitting displays (micro-LED), mini light emitting displays (mini-LED), quantum dot light emitting displays (QLED), and the like have been developed and widely used.

Display devices are required to provide excellent display quality and emission efficiency. In particular, as display technology advances, to provide various functions and produce an excellent performance, display devices are desired to use limited power, and the emission efficiency of display devices is becoming increasingly important.

The emission efficiency of display devices can be determined by light emitting elements included in the display devices. A display device including light emitting elements with excellent emission efficiency can have excellent emission efficiency. For example, the emission efficiency of a display device can be improved by improving the emission efficiency of light emitting elements included in the display device. However, challenges can arise in improving the emission efficiency of light emitting elements.

### SUMMARY

To address this issue, one or more embodiments of the present disclosure may provide a display device that has a structure where one subpixel includes a double-layered pixel electrode, and thereby, is capable of producing improved light emission efficiency,

One or more embodiments of the present disclosure may provide a display device that has a structure where one subpixel includes a double-layered pixel electrode, and thereby, is capable of eliminating or reducing display artifacts such as stained image presenting and the like.

One or more embodiments of the present disclosure may provide a display device that has a structure where one subpixel includes a plurality of light emitting areas emitting light of the same color, and thereby, is capable of being driven with low power through high luminance characteristics.

According to one or more example embodiments of the present disclosure, a display device can be provided that includes a substrate on which a plurality of subpixels are disposed, each of the plurality of subpixels including a plurality of light emitting areas, a first planarization layer disposed over the substrate, a first pixel electrode disposed on the first planarization layer, a second planarization layer disposed on the first pixel electrode and including at least one opened portion exposing at least a portion of the upper surface of the first pixel electrode, a second pixel electrode disposed on the second planarization layer, a bank disposed on a portion of the upper surface of the second pixel electrode and including an opening in each of the plurality of subpixels, an emission layer disposed in the opening, and a common electrode disposed on the emission layer.

According to one or more example embodiments of the present disclosure, a display device can be provided that includes a plurality of light emitting areas disposed in one subpixel, the plurality of light emitting areas including at least one first light emitting area disposed in the subpixel, a second light emitting area surrounding the first light emitting area, and a third light emitting area surrounding the second light emitting area, and at least one opened portion located in one subpixel and allowing the first light emitting area and the second light emitting area to be disposed.

According to one or more embodiments of the present disclosure, a display device may be provided that is capable of eliminating or reducing display artifacts such as stained image presenting and the like and improving light emission efficiency.

According to one or more embodiments of the present disclosure, a display device may be provided that is capable of producing improved light emission efficiency based on a structure where one subpixel includes a double-layered pixel electrode.

According to one or more embodiments of the present disclosure, a display device may be provided that is capable of eliminating or reducing display artifacts such as stained image presenting and the like based on a structure where one subpixel includes a double-layered pixel electrode.

According to one or more embodiments of the present disclosure, a display device may be provided that is capable of being driven with low power through high luminance characteristics based on a structure where one subpixel includes a plurality of light emitting areas emitting light of the same color.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to an embodiment of the present disclosure;

FIG. 2 illustrates an example display panel according to an embodiment of the present disclosure;

FIG. 3 is a plan view illustrating an example area of a subpixel disposed in an active area of the display panel according to an embodiment of the present disclosure;

FIG. 4 is a cross-sectional view taken along line A-B of FIG. 3 according to an embodiment of the present disclosure;

FIG. 5 is a cross-sectional view illustrating light emitting areas of FIG. 4 according to an embodiment of the present disclosure;

FIGS. 6A to 6E are example plan views schematically illustrating the structure of four subpixels in the display device according to embodiments of the present disclosure;

FIGS. 7A to 7J illustrate an example method of manufacturing a display device according to embodiments of the present disclosure; and

FIG. 8 is a cross-sectional view schematically illustrating an example structure of the display device according to embodiments of the present disclosure.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Although the terms “first,” “second,” “A”, “B”, “(a)”, or “(b)”, and the like may be used herein to describe various elements, these elements should not be interpreted to be limited by these terms as they are not used to define a particular order or precedence. These terms are used only to distinguish one element from another; thus, related elements should not be interpreted to be limited by these terms as they are not used to define a particular order or precedence.

Further, the expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, another element may be included in one or more of the two or more elements connected, combined, coupled, or contacted (to) one another.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

In construing an element, the element is to be construed as including an error or tolerance range even where no explicit description of such an error or tolerance range is provided. Further, the term “may” fully encompasses all the meanings of the term “can.”

The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

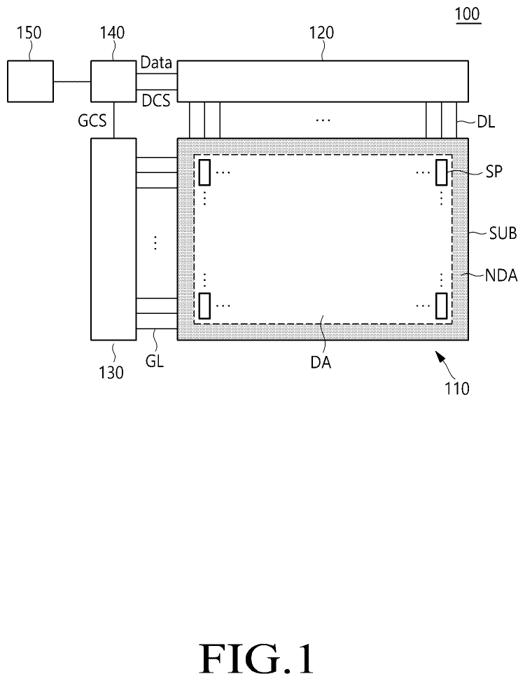

FIG. 1 illustrates an example system configuration of a display apparatus 100 according to embodiments of the present disclosure. All components of each display apparatus according to all aspects of the present disclosure are operatively coupled and configured.

Referring to FIG. 1, in one or more embodiments, the display device 100 may include a display panel 110 and a display driving circuit as components for displaying an image.

The display driving circuit may be a circuit for driving the display panel 110, and include a data driving circuit 120, a gate driving circuit 130, a display controller 140, and other circuit components.

The display panel 110 may include an active area DA allowing an image to be displayed and a non-active area NDA in which an image is not displayed. The non-active area NDA may be an area outside of the active area DA, and may also be referred to as a bezel area or a bezel. All or at least part of the non-active area NDA may be an area visible from the front surface of the display device 100, or an area that is bent and invisible from the front surface of the display device 100.

The display panel 110 may include a substrate SUB and a plurality of subpixels SP disposed on the substrate SUB. The display panel 110 may further include various types of signal lines to drive the plurality of subpixels SP.

In one or more embodiments, the display device 100 may be a liquid crystal display device, or the like, or a self-emission display device in which light is emitted from the display panel 110 itself. In an example where the display device 100 is a self-emission display device, each of the plurality of subpixels SP may include a light emitting element.

For example, the display device 100 according to aspects of the present disclosure may be an organic light emitting display device in which light emitting elements ED are implemented using organic light emitting diodes (OLED). In another example, the display device 100 according to aspects of the present disclosure may be an inorganic light emitting display device in which light emitting elements are implemented using inorganic material-based light emitting diodes. In further another example, the display device 100 according to aspects of the present disclosure may be a quantum dot display device implemented with quantum dots, which are self-emission semiconductor crystals, as light emitting elements.

The structure of each of the plurality of subpixels SP may be differently configured or designed according to types of the display devices 100. In an example where the display device 100 is a self-emission display device including self-emission subpixels SP, each subpixel SP may include a self-emission light emitting element, one or more transistors, and one or more capacitors.

The various types of signal lines arranged in the display device 100 may include, for example, a plurality of data lines DL for delivering data signals (which may be referred to as data voltages or image signals), a plurality of gate lines GL for delivering gate signals (which may be referred to as scan signals), and the like.

The plurality of data lines DL and the plurality of gate lines GL may intersect one another. Each of the plurality of data lines DL may be configured to extend in a first direction. Each of the plurality of gate lines GL may be configured to extend in a second direction.

For example, the first direction may be the column or vertical direction, and the second direction may be the row or horizontal direction. In another example, the first direction may be the row or horizontal direction, and the second direction may be the column or vertical direction.

The data driving circuit 120 may be a circuit for driving the plurality of data lines DL, and can supply data signals to the plurality of data lines DL. The gate driving circuit 130 may be a circuit for driving a plurality of gate lines GL, and can supply gate signals to the plurality of gate lines GL.

The display controller 140 may be a device for controlling the data driving circuit 120 and the gate driving circuit 130. The display controller 140 can control driving times for the plurality of data lines DL and driving times for the plurality of gate lines GL.

The display controller 140 can supply data driving control signals DCS to the data driving circuit 120 to control the data driving circuit 120. The display controller 140 can supply gate driving control signals GCS to the gate driving circuit 130 to control the gate driving circuit 130.

The display controller 140 can receive input image data from a host system 150 and supply image data Data readable by the data driving circuit 120 based on the input image data to the data driving circuit 120.

The data driving circuit 120 can supply data signals to the plurality of data lines DL according to driving timing control of the display controller 140.

The data driving circuit 120 can receive digital image data Data from the display controller 140, convert the received image data Data into analog data signals, and output the resulting analog data signals to the plurality of data lines DL.

The gate driving circuit 130 can supply gate signals to the plurality of gate lines GL according to timing control of the display controller 140. The gate driving circuit 130 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more embodiments, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more embodiments, the gate driving circuit 130 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more embodiments, the gate driving circuit 130 may be disposed in the non-active area NDA of the display panel 110 by a gate-in-panel (GIP) technique. The gate driving circuit 130 may be disposed on the substrate SUB, or connected to the substrate SUB. In an example where the gate driving circuit 130 is implemented by the GIP technique, the gate driving circuit 130 may be disposed in the non-active area NDA of the substrate SUB. The gate driving circuit 130 may be connected to the substrate SUB in an example where the gate driving circuit 130 is implemented by the chip-on-glass (COG) technique, the chip-on-film (COF) technique, or the like.

In one or more embodiments, at least one of the data driving circuit 120 and the gate driving circuit 130 may be disposed in the active area DA of the display panel 110. For example, at least one of the data driving circuit 120 and the gate driving circuit 130 may be configured not to overlap with subpixels SP, or configured to overlap with one or more, or all, of the subpixels SP, or at least respective one or more portions of one or more subpixels.

The data driving circuit 120 may be disposed in, and/or electrically connected to, but not limited to, one side or edge (e.g., an upper portion or a lower portion) of the display panel 110. In one or more aspects, the data driving circuit 120 may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 130 may be located in, and/or electrically connected to, but not limited to, one side or edge (e.g., a left portion or a right portion) of the display panel 110. In one or more embodiments, the gate driving circuit 130 may be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The display controller 140 may be implemented in a separate component from the data driving circuit 120, or incorporated in the data driving circuit 120 and thus implemented in an integrated circuit.

The display controller 140 may be a timing controller used in the typical display technology or a controller or a control device capable of performing other control functions in addition to the function of the typical timing controller. In one or more embodiments, the display controller 140 may be a controller or a control device different from the timing controller, or a circuitry or a component included in the controller or the control device. The display controller 140 may be implemented with various circuits or electronic components such as an integrated circuit (IC), a field programmable gate array (FPGA), an application specific integrated circuit (ASIC), a processor, and/or the like.

The display controller 140 may be mounted on a printed circuit board, a flexible printed circuit, and/or the like and be electrically connected to the gate driving circuit 120 and the data driving circuit 130 through the printed circuit board, flexible printed circuit, and/or the like.

The display controller 140 can transmit signals to, and receive signals from, the data driving circuit 120 via one or more predefined interfaces. For example, such interfaces may include, a low voltage differential signaling (LVDS) interface, an embedded clock point-point interface (EPI), a serial peripheral interface (SPI), and the like.

In some embodiments, the display device 100 may be a mobile terminal such as a smart phone, a tablet, or the like, or a monitor, a television (TV), or the like. Such devices may be configured in various types, sizes, and shapes. The display device 100 according to aspects of the present disclosure are not limited thereto, and may include various types, sizes, and shapes configured to display information or images.

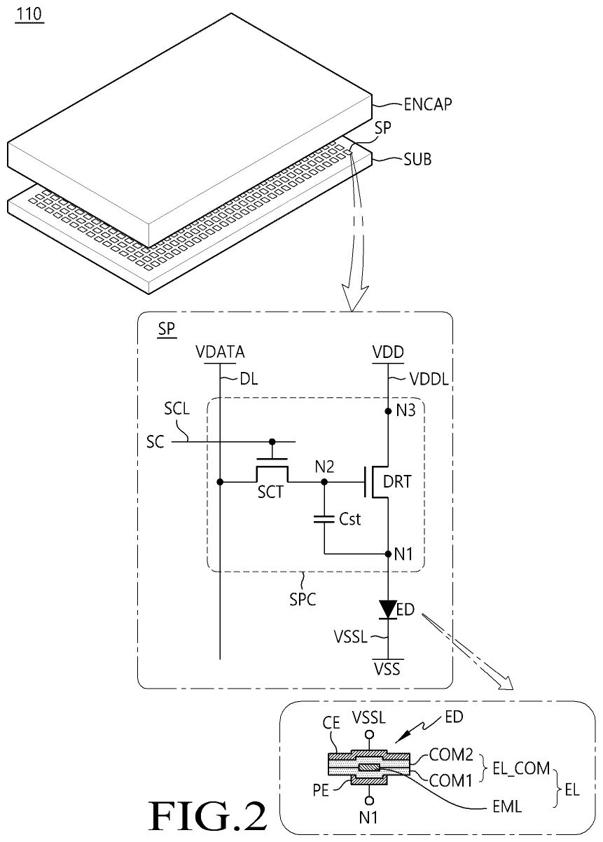

FIG. 2 illustrates an example configuration of the display panel 110 according to aspects of the present disclosure.

Referring to FIG. 2, the display panel 110 may include a substrate SUB on which a plurality of subpixels SP are disposed, and an encapsulation layer ENCAP over the substrate SUB. The encapsulation layer ENCAP may also be referred to as an encapsulation substrate or an encapsulation stack.

Referring to FIG. 2, in an example where the display device 100 is a self-emission display device, each of the plurality of subpixels SP disposed on the substrate SUB may include a light emitting element ED and a subpixel circuit SPC for driving the light emitting element ED.

Referring to FIG. 2, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DRT for driving the light emitting element ED and a scan transistor SCT configured to be turned on or off according to a scan signal SC.

The driving transistor DRT can supply a driving current to the light emitting element ED.

The scan transistor SCT may be configured to control an electrical state of a corresponding node in the subpixel circuit SPC or to control the state or operation of the driving transistor DRT.

The at least one capacitor may include a storage capacitor Cst configured to maintain a constant voltage during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, a common pixel driving voltage including a first common driving voltage VDD and a second common driving voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions may be provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed in each subpixel SP, and the common intermediate layer EL_COM may be commonly disposed across all or some of a plurality of subpixels SP.

The emission layer EML may be disposed in each light emitting area, and the common intermediate layer EL_COM may be commonly disposed across all or some of a plurality of light emitting areas and all or some of a plurality of non-light emitting areas.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like. But aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a second common driving voltage line VSSL. A second common driving voltage VSS, which is a type of common pixel driving voltage, may be applied to the common electrode CE through the second common driving voltage line VSSL. The pixel electrode PE may be electrically connected directly or indirectly (via another transistor) to a first node N1 of a corresponding driving transistor DRT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.

Each light emitting element ED may be configured by overlap of the pixel electrode PE, the emission layer in the intermediate layer EL, and the common electrode CE. Each light emitting area may be formed by a corresponding light emitting element ED. For example, a corresponding light emitting area of each light emitting element ED may include an overlapping area of the pixel electrode PE, the emission layer in the intermediate layer EL, and the common electrode CE.

In one or more embodiments, the light emitting element ED may be an organic light emitting diode (OLED), an inorganic light emitting diode (LED), a quantum dot light emitting element, or the like. For example, in an example where the light emitting element ED is an organic light emitting diode OLED, the intermediate layer EL of the light emitting element ED may be a layer including an organic material.

The driving transistor DRT may be a transistor configured to supply a driving current to the light emitting element ED. The driving transistor DRT may be connected between a first common driving voltage line VDDL and the light emitting element ED.

The driving transistor DRT may include a first node N1, a second node N2, and a third node N3. The first node NI may be electrically connected to the light emitting element ED. A data signal VDATA may be applied to the second node N2. The first common driving voltage VDD may be applied to the third node N3 through the first common driving voltage line VDDL.

In the driving transistor DRT, the second node N2 may be a gate node, the first node N1 may be a source node or a drain node, and the third node N3 may be the drain node or the source node. Hereinafter, for merely convenience of explanation, discussions are provided based on examples where the first, second, and third nodes (N1, N2, and N3) of the driving transistor DRT are source, gate, and drain nodes, respectively. However, aspects of the present disclosure are not limited thereto.

The scan transistor SCT included in the subpixel circuit SPC illustrated in FIG. 2 may be a switching transistor for allowing a data signal VDATA, which is an image signal, to be supplied to the second node N2, which is the gate node of the driving transistor DRT.

The scan transistor SCT can be turned on or turned off by a scan signal SC, which is a type of gate signal, applied through a scan line SCL, which is a type of gate line GL, and control an electrical connection between the second node N2 of the driving transistor DRT and a data line DL. The drain electrode or source electrode of the scan transistor SCT may be electrically connected to the data line DL. The source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The storage capacitor Cst may be an external capacitor intentionally designed to be located or disposed outside of the driving transistor DRT, and therefore, be different from an internal capacitor such as a parasitic capacitor (e.g., a Cgs, a Cgd) that may be formed between the first node N1 and the second node N2 of the driving transistor DRT.

Each of the driving transistor DRT and the scan transistor SCT may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can be increased, and a corresponding aperture ratio can be increased.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DRT and SCT) and one capacitor (1C: Cst) (which may be referred to as a “2T1C structure”), and in some implementations, may further include one or more transistors, and/or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitors. In further another example, the subpixel circuit SPC may have an 7T1C structure including 7 transistors and 1 capacitor.

The types and number of gate signals supplied to a subpixel SP, and/or the types and number of gate lines connected to the subpixel SP may vary depending on a structure of a corresponding subpixel circuit SPC. Further, the types and number of common pixel driving voltages supplied to a subpixel SP may vary depending on a structure of a corresponding subpixel circuit SPC.

Since circuit elements (in particular, a light emitting element ED implemented with an organic light emitting diode including an organic material) included in each subpixel SP are vulnerable to external moisture or oxygen, an encapsulation layer ENCAP may be disposed in the display panel 110 in order to prevent or at least reduce external moisture or oxygen from penetrating into such circuit elements. The encapsulation layer 200 may be disposed in various shapes or configurations to prevent light emitting elements ED from contacting moisture or oxygen.

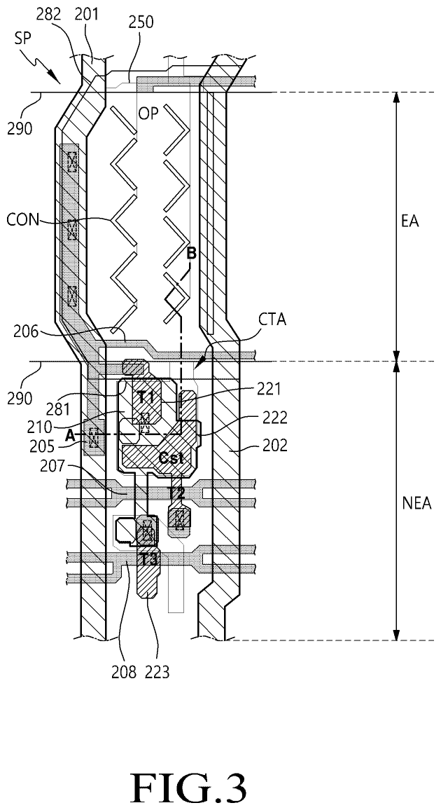

FIG. 3 is a plan view illustrating an example area of a subpixel SP disposed in the active area of the display panel 110 according to embodiments of the present disclosure.

Referring to FIG. 3, in one or more embodiments, at least one of a plurality of subpixels SP included in the display device 100 may include an area overlapping with a bank 290 and an area overlapping with an opening OP of the bank 290.

The area overlapping with the bank 290 may include a non-light emitting area NEA. A plurality of signal lines (201, 202, 205, 206, 207, and 208), a light shield 210, and a plurality of active layers (221, 222, and 223) may be disposed in the non-light emitting area NEA. The plurality of signal lines may include first to sixth signal lines (201, 202, 205, 206, 207, and 208), and the plurality of active layers may include first to third active layers (221, 222, and 223). The non-light emitting area NEA may include a circuit area.

Referring to FIG. 3, a plurality of transistors (T1, T2, and T3) and a storage capacitor Cst for driving a light emitting element included in a subpixel SP may be disposed in the area overlapping with the bank 290.

For example, a corresponding light emitting element including a first electrode, an organic layer, and a second electrode may be disposed in each opening OP of the bank 290. In one or more aspects, color filters (281, 282) may be disposed in an area overlapping with the opening OP, but aspects of the present disclosure are not limited thereto. For example, color filters (281, 282) may be disposed only in some of subpixels SP included in the display device 100, or color filters (281, 282) may not be disposed in all of the subpixels SP included in the display device 100.

Referring to FIG. 3, a corresponding light emitting area EA of each light emitting element included in the display device 100 may be formed in an area overlapping with each opening OP of the bank 290.

Referring to FIG. 3, at least one opened portion CON may be disposed in one opening OP of the bank 290 located in one subpixel SP.

The at least one opened portion CON disposed in the one opening OP may be formed such that a plurality of opened portions CON spaced apart from each other are disposed in the opening OP. For example, the plurality of opened portions CON may be disposed spaced apart in a column direction or a row direction in the opening OP.

Referring to FIG. 3, for example, the plurality of opened portions CON may be disposed in a pattern in which one or more opened portions CON with a rightward opened angle bracket shape are spaced apart in a column direction, and one or more opened portions CON with a leftward opened angle bracket shape are spaced apart in the column direction.

Although FIG. 3 illustrates that the plurality of opened portions disposed in at least one subpixel SP are configured with angle bracket shapes, however, opened portions CON of the display device 100 according to aspects of the present disclosure may be formed in various shapes.

Referring to FIG. 3, the plurality of opened portions CON overlapping with one opening OP in at least one subpixel SP may overlap with color filters (281, 282).

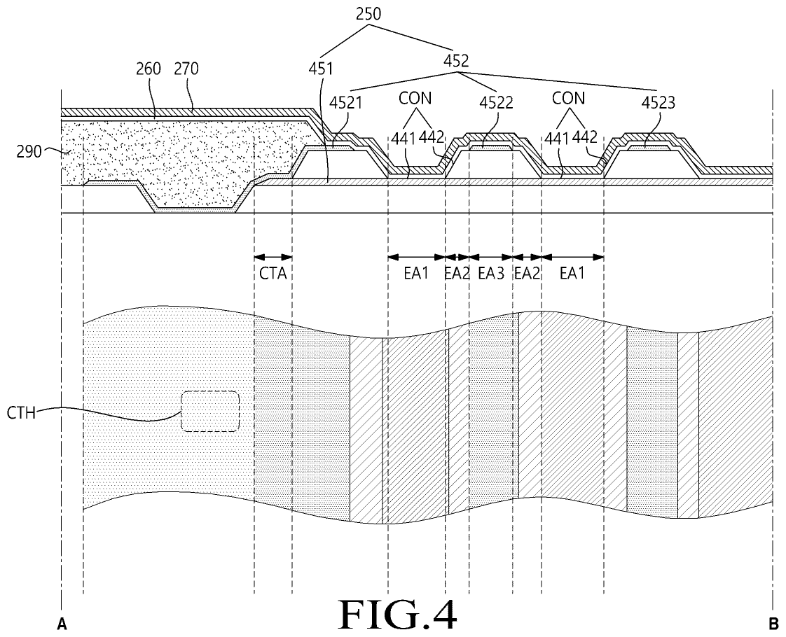

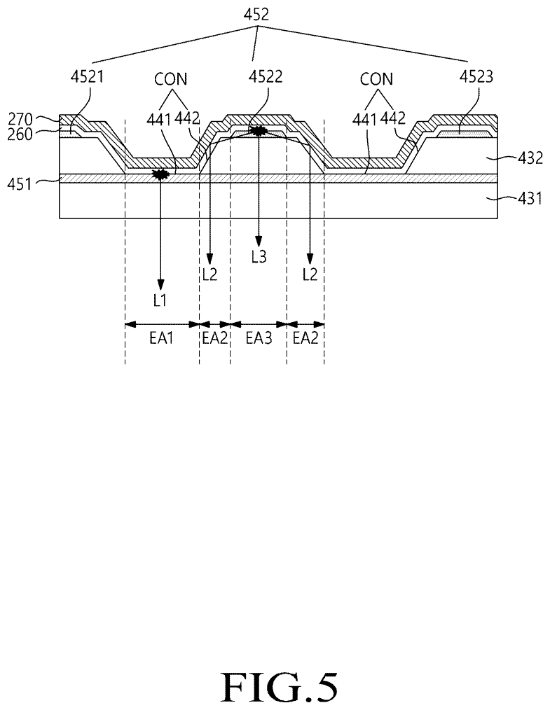

FIG. 4 is a cross-sectional view taken along line A-B of FIG. 3 according to one embodiment. FIG. 5 is a cross-sectional view illustrating light emitting areas of FIG. 4 according to one embodiment.

Referring to FIGS. 4 and 5, a first planarization layer 431 may be disposed. The first planarization layer 431 may include a hole in an area corresponding to a contact hole CTH. The first planarization layer 431 may include an organic insulating material or an inorganic insulating material, but aspects of the present disclosure are not limited thereto.

A first pixel electrode 451 may be disposed on the first planarization layer 431. The first pixel electrode 451 may be disposed adjacent to the hole of the first planarization layer 341 disposed in the area corresponding to the contact hole CTH.

A second planarization layer 432 may be disposed on the first pixel electrode 451.

The second planarization layer 432 may include opened portions CON (i.e., at least part of the plurality of opened portions CON included in FIG. 2). The second planarization layer 432 may include an organic insulating material or an inorganic insulating material, but aspects of the present disclosure are not limited thereto.

Each of the opened portions CON may include a lower surface 441 in which the second planarization layer 432 is removed and the first pixel electrode 451 is exposed. Each opened portion CON may include an inclined surface 442 extending along a side surface of the second planarization layer 432 from the lower surface 441.

The second planarization layer 432 may include an upper surface extending from the side surface of the second planarization layer 432 or the inclined surface 442.

A second pixel electrode 452 may be disposed on the upper surface of the second planarization layer 432.

The second pixel electrode 452 may include two or more second pixel electrode portions (4521, 4522, 4523) spaced apart by one or more opened portions CON.

The second pixel electrode 452 may be configured to extend from the second planarization layer 432 to a circuit area where the contact hole CTH is located. The second pixel electrode 452 may extend to the circuit area and be electrically connected to a thin film transistor through the contact hole CTH.

The first pixel electrode 451 and the second pixel electrode 452 may be electrically connected in a contact area CTA on a side surface of the second planarization layer 432. For example, one portion 4521 of the second pixel electrode 452 and one end or edge of the first pixel electrode 451 may be electrically connected at the contact area CTA.

The first pixel electrode 451 and the second pixel electrode 452 may form a pixel electrode 250 included in one subpixel SP.

The pixel electrode 250 may include a transparent conductive material. The transparent conductive material may include a transparent conductive oxide (TCO). For example, the transparent conductive oxide (TCO) may include one or more of indium zinc oxide (IZO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), fluorine-doped transparent oxide (FTO), and the like. However, the material of the pixel electrode 250 according to aspects of the present disclosure is not limited thereto. For example, the pixel electrode 250 may include any material having high light transmittance and high conductivity.

The first pixel electrode 451 and the second pixel electrode 452 may include, for example, the same transparent conductive oxide. In one or more aspects, the first pixel electrode 451 and the second pixel electrode 452 may include different transparent conductive oxides.

For example, in the display device 100 according to embodiments of the present disclosure, the first pixel electrode 451 may include a high-refractive electrode material, and the second pixel electrode 452 may include a low-refractive electrode material. For example, the first pixel electrode 451 may be indium zinc oxide (IZO), and the second pixel electrode 452 may be indium tin oxide (ITO).

Referring to FIGS. 4 and 5, the first pixel electrode 451 and the second pixel electrode 452 may be configured not to overlap with each other in one or more opened portions CON.

Referring to FIGS. 4 and 5, a bank 290 may be disposed on a portion of the upper surface of the second pixel electrode 452. The bank 290 may have at least one opening OP in one subpixel.

The bank 290 may include a transparent organic material or include a black organic material.

Referring to FIGS. 4 and 5, the opening OP of the bank 290 may overlap with opened portions CON disposed between portions of the second pixel electrode 452.

Referring to FIGS. 4 and 5, an emission layer 260 may be disposed on the pixel electrode 250, the bank 290, and the second planarization layer 432, and a common electrode 270 may be disposed on the emission layer 260.

FIGS. 4 and 5 illustrates that the emission layer 260 and the common electrode 270 has a single-layer structure, but aspects of the present disclosure are not limited thereto. For example, at least one of the emission layer 260 and the common electrode 270 may have a multi-layer structure.

Referring to FIGS. 4 and 5, the emission layer 260 and the common electrode 270 may be disposed on the bank 290 and in the opening OP of the bank 290.

The common electrode 270 may include a conductive material capable of reflecting light. For example, the common electrode 270 may include any one of metals such as aluminum (Al), magnesium (Mg), gold (Au), silver (Ag), copper (Cu), tungsten (W), molybdenum (Mo), chromium (Cr), tantalum (Ta), titanium (Ti), or the like, or any one of one or more alloys thereof, but embodiments of the present disclosure are not limited thereto.

Referring to FIGS. 4 and 5, the emission layer 260 and the common electrode 270 may be disposed in one or more opened portions CON formed in the second planarization layer 432 overlapping with the opening OP of the bank 290. In one or more embodiments, the emission layer 260 and the common electrode 270 may also be disposed in one or more areas where the second pixel electrode 452 exposes one or more portions of the upper surface of the second planarization layer 432 in one or more areas adjacent to one or more opened portions CON formed in the second planarization layer 432.

Referring to FIGS. 4 and 5, the emission layer 260 and the common electrode 270 may be formed along the morphology of the second pixel electrode 452 and the second planarization layer 432 in the opening OP of the bank 290. Therefore, the emission layer 260 and the common electrode 270 may have a slope in the opening OP of the bank 290.

Referring to FIGS. 4 and 5, a plurality of light emitting areas (EA1, EA2, EA3) may be formed in one subpixel.

Referring to FIGS. 4 and 5, the first pixel electrode 451, the emission layer 260, and the common electrode 270 may be configured to be stacked on the lower surface 441 of one or more opened portions CON. A first light emitting area EA1 may be formed in an area corresponding to the lower surface 441. The first light emitting area EA1 may be a light emitting area through which among light emitted from the first pixel electrode 451, the emission layer 260, and the common electrode 270, some light L1 is directed outside of the display device 100.

Referring to FIGS. 4 and 5, the emission layer 260 and the common electrode 270 may be configured to be stacked on the inclined surface 442 of one or more opened portions CON. A second light emitting area EA2 may be formed in an area corresponding to the inclined surface 442. The second light emitting area EA2 may be a light emitting area through which among light emitted from the second pixel electrode 452, the emission layer 260, and the common electrode 270, some light L2 is directed outside of the display device 100 after traveling sideways and being reflected from the common electrode 270 disposed on the inclined surface 442.

Referring to FIGS. 4 and 5, the second pixel electrode 452, the emission layer 260, and the common electrode 270 may be configured to be stacked on the upper surface of the second planarization layer 432. A third light emitting area EA3 may be formed on an area corresponding to the upper surface of the second planarization layer 432. The third light emitting area EA3 may be a light emitting area through which among light emitted from the first pixel electrode 452, the emission layer 260, and the common electrode 270, some light L3 is directed outside of the display device 100.

Referring to FIGS. 4 and 5, the second light emitting area EA2 may be configured to surround the first light emitting area EA1. The third light emitting area EA3 may be configured to surround the second light emitting area EA2.

According to these configurations, based on the structure where the second planarization layer 432 has at least one opened portion CON and an upper surface in one subpixel, light emitted from the first light emitting area EA1 provided on the lower surface 441 of the opened portion CON and the third light emitting area EA3 provided on the upper surface of the second planarization layer 342 can be directed outside of the display device 100. In this situation, among light emitted from the third light emitting area EA3, some light traveling sideways can be reflected from the common electrode 270 disposed on the inclined surface 442 of the opened portion CON and thereafter, be directed outside of the display device 100. Thus, since light emitted from the emission layer 260 can be directed outside of the display device 100 without loss through the first light emitting area EA1, the second light emitting area EA2, and the third light emitting area EA3, the display device 100 can have the capability of improving light emission efficiency.

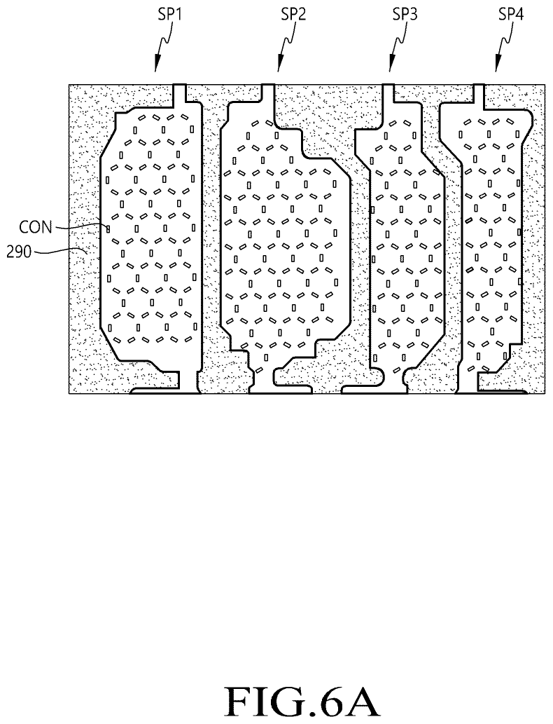

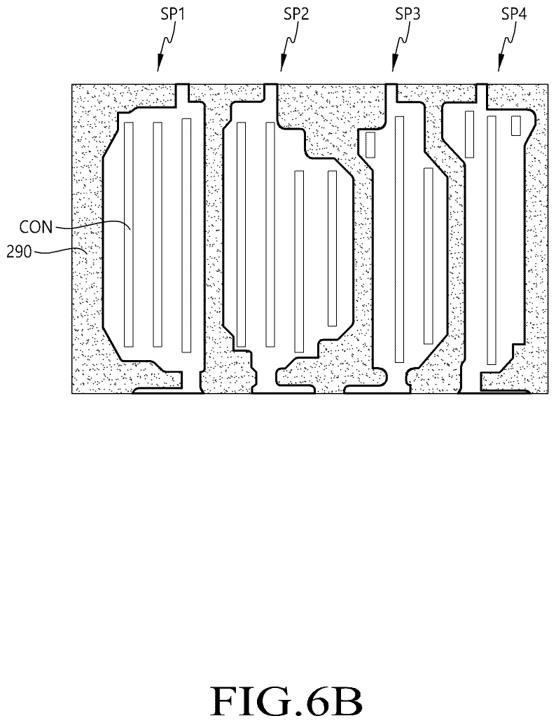

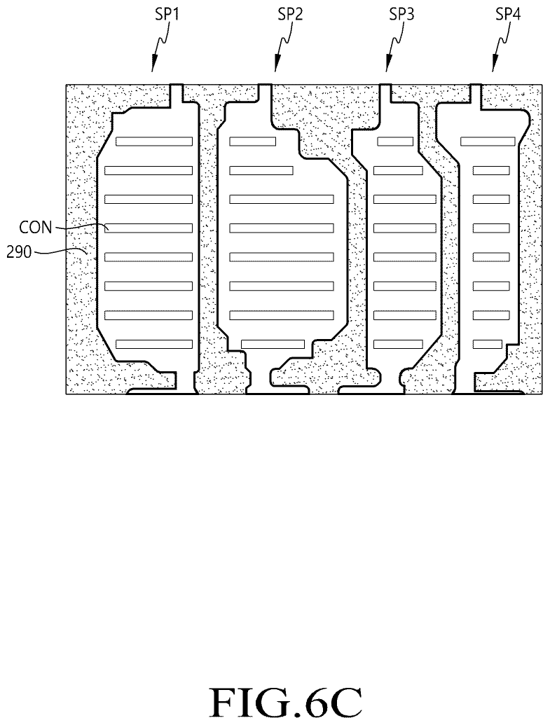

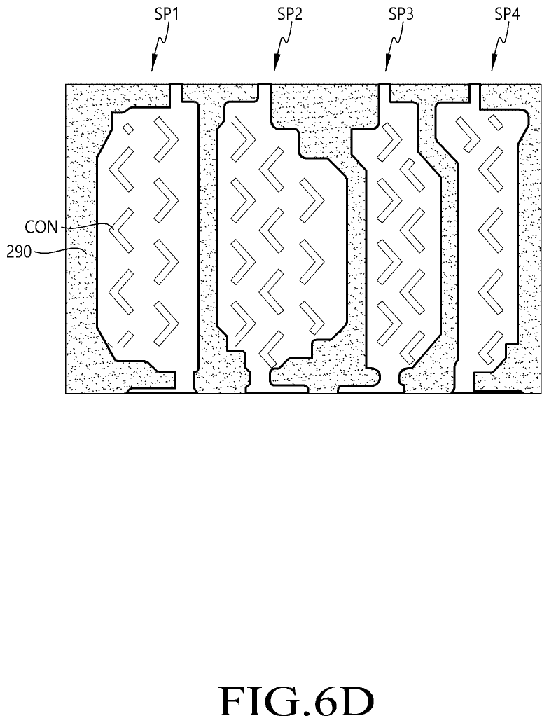

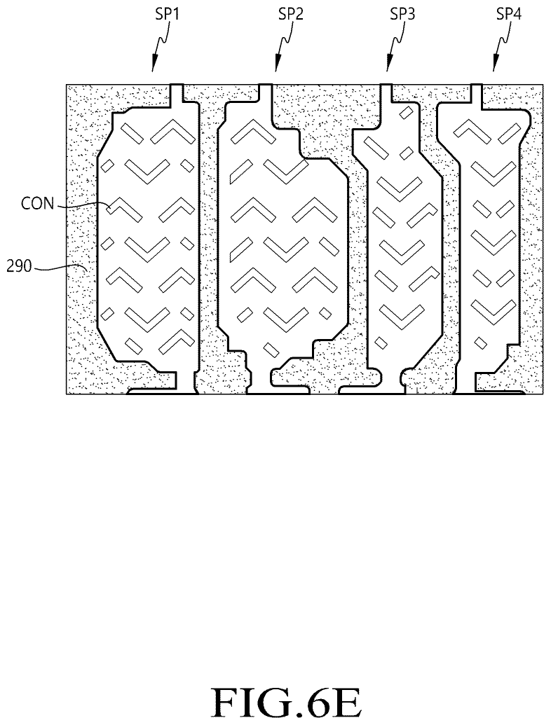

FIGS. 6A to 6E are example plan views schematically illustrating the structure of four subpixels in the display device 100 according to aspects of the present disclosure.

Referring to FIGS. 6A to 6E, in one or more embodiments, in the display device 100, a plurality of opened portions CON may be formed in a light emitting area, which is an area corresponding to an opening OP of the bank 290. The plurality of opened portions CON may be configured to be spaced apart from each other in one subpixel. The plurality of opened portions CON may be disposed in a polygonal shape. The plurality of opened portions CON may be spaced apart from each other in a column direction or a row direction in one subpixel.

Referring to FIG. 6A, the plurality of opened portions CON disposed in one opening OP of the bank 290 may be disposed in a structure in which polygonal shapes with open corners (a shape in which the opened portions CON are not disposed at corners of the polygonal shape) are connected to each other.

For example, the plurality of opened portions CON may be disposed in a structure in which six opened portions CON forms a single hexagonal shape with open corners, and a plurality of hexagonal shapes, each of which includes six opened portions CON, are disposed. In this example, one hexagon shape may be configured to share at least one opened portion CON with an adjacent hexagon shape.

Referring to FIG. 6B and FIG. 6C, the plurality of opened portions CON may be spaced apart from each other. Referring to FIG. 6B, a plurality of opened portions CON may be disposed such that each opened portion CON extends lengthwise in the column direction, and the plurality of opened portions CON are spaced apart from each other in the row direction. Referring to FIG. 6C, a plurality of opened portions CON may be disposed such that each opened portion CON extends lengthwise in the row direction, and the plurality of opened portions CON are spaced apart from each other in the column direction.

Referring to FIG. 6D and FIG. 6E, a plurality of opened portions CON may be disposed in a predefined pattern and be spaced apart from each other. Referring to FIG. 6D, the plurality of opened portions CON may be disposed in a pattern in which opened portions CON with a rightward opened angle bracket shape and opened portions CON with a leftward opened angle bracket shape are spaced apart in the column direction. Referring to FIG. 6E, the plurality of opened portions CON may be disposed in a pattern in which opened portions CON with an upward opened angle bracket shape and opened portions CON with a downward opened angle bracket shape are spaced apart in the column direction.

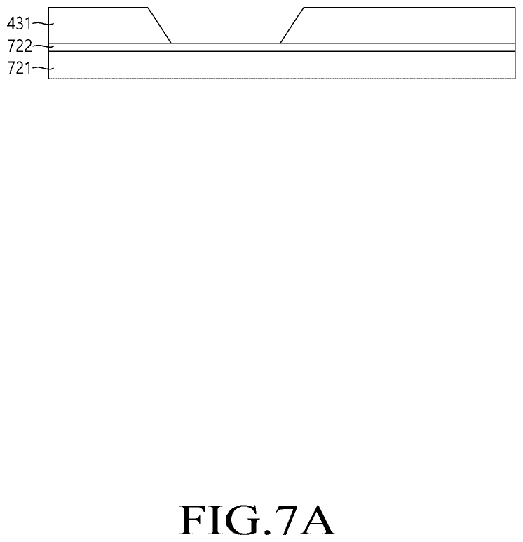

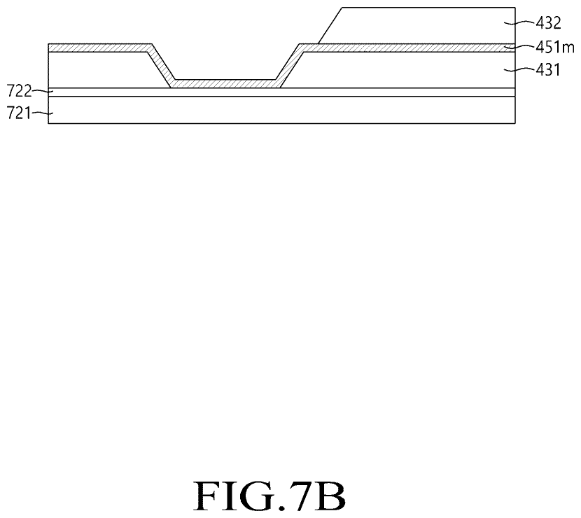

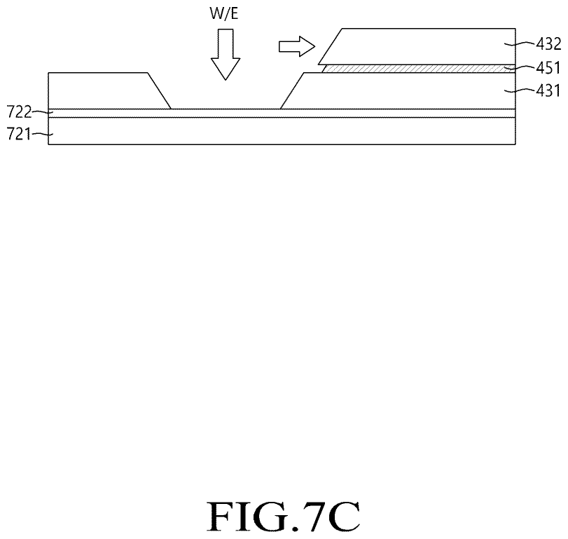

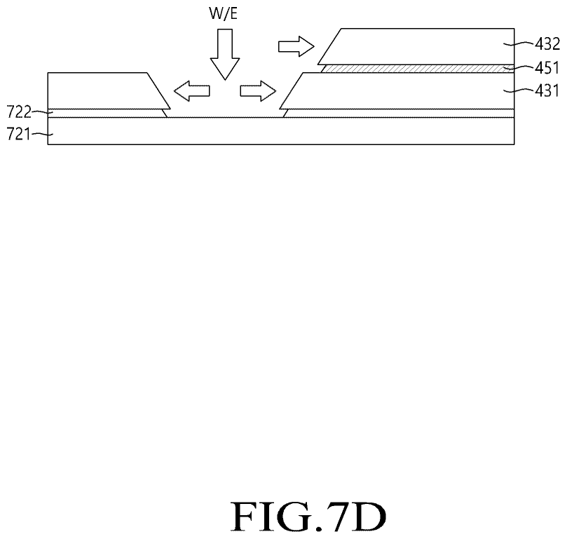

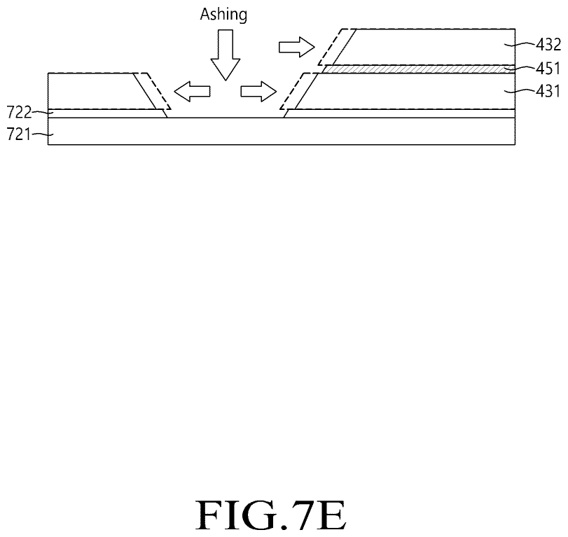

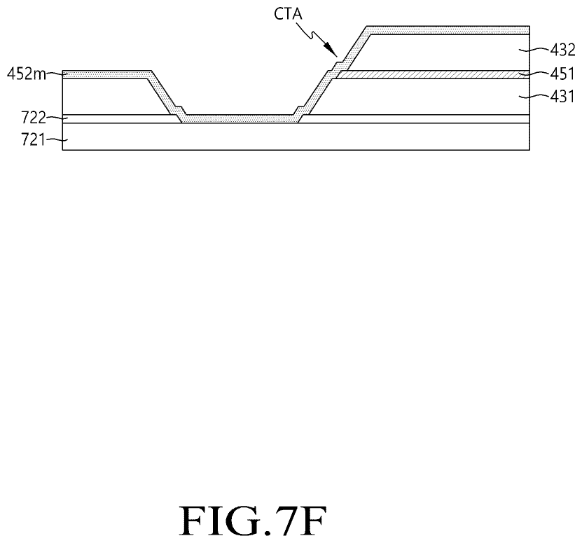

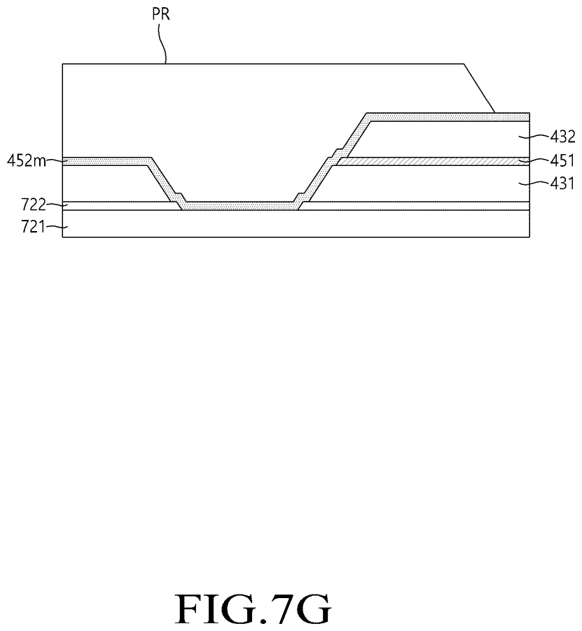

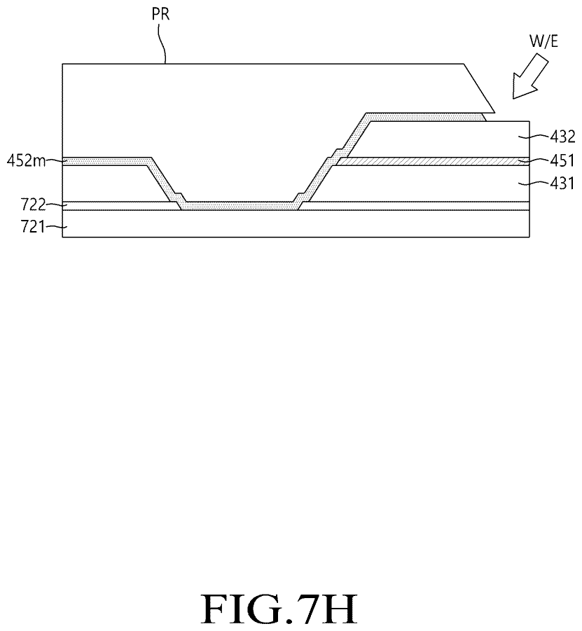

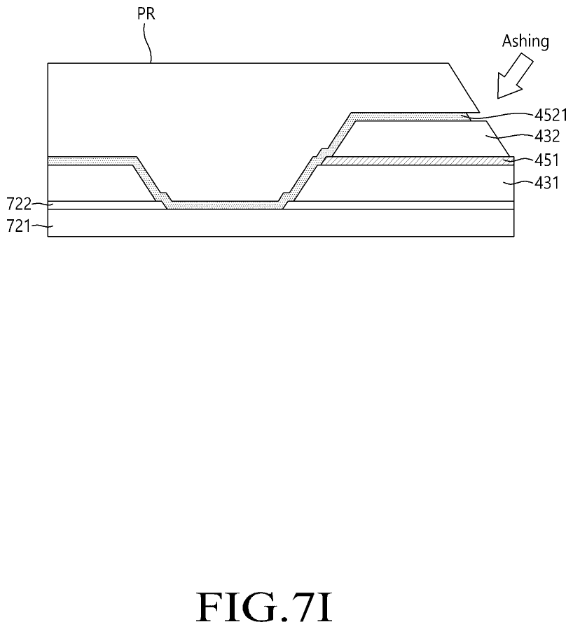

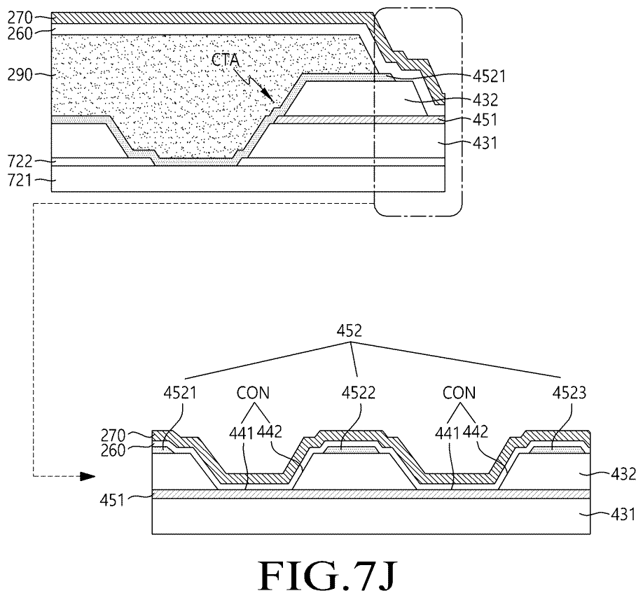

FIGS. 7A to 7J illustrate an example method of manufacturing a display device (e.g., the display device 100 discussed above) according to embodiments of the present disclosure.

First, as illustrated in FIG. 7A, a first planarization layer 431 may be formed on a lower insulating layer 721 and an upper insulating layer 722. The first planarization layer 431 may be patterned so that a hole can be formed in an area corresponding to a contact hole.

Next, as illustrated in FIG. 7B, a first pixel electrode material layer 451m may be formed on the first planarization layer 431 and the upper insulating layer 722, and thereafter, a second planarization layer 432 may be applied and patterned on the first pixel electrode material layer 451m.

Next, as illustrated in FIG. 7C, a portion of the first pixel electrode material layer 451m may be etched by a wet etching (W/E) process. The wet etching process may be a process of etching the first pixel electrode material layer 451m to form a first pixel electrode 451.

Next, as illustrated in FIG. 7D, a portion of the upper insulating layer 722 may be etched by a wet etching (W/E) process. The wet etching process may be a process of etching the portion of the upper insulating layer 722 to form the contact hole.

Next, as illustrated in FIG. 7E, respective portions of the first planarization layer 431 and the second planarization layer 432 may be removed by an ashing process. The ashing process may be a process of removing the portions of the first planarization layer 431 and the second planarization layer 432 so that a portion of the first pixel electrode 451 disposed between the first planarization layer 431 and the second planarization layer 432 can be exposed to a contact area.

Next, as illustrated in FIG. 7F, a second pixel electrode material layer 452m may be formed on the top surface. The second pixel electrode material layer 452m may contact the exposed portion of the first pixel electrode 451 at the contact area CTA.

Next, as illustrated in FIGS. 7G and 7H, a photoresist PR may be applied to a portion of the second pixel electrode material layer 452m, and a portion of the second pixel electrode material layer 452m may be etched by a wet etching process. Thereby, a second pixel electrode may be formed. The wet etching (W/E) process may be a process of removing the portion of the second pixel electrode material layer 452m to form the second pixel electrode with a hole.

Thereafter, as illustrated in FIG. 7I, a portion of the second planarization layer 432 exposed to the hole of the second pixel electrode 452 may be removed by an ashing process. After the ashing process is performed, the photoresist PR may be removed. The ashing process may be a process of forming an opened portion by removing the portion of the second planarization layer 432. A second pixel electrode portion 4521 illustrated in FIG. 7I may be one of two or more portions of the pixel electrode 452.

Next, as illustrated in FIG. 7J, a bank 290 may be formed on the second pixel electrode portion 4521. After the bank 290 is formed, an emission layer 260 and a common electrode 270 may be formed sequentially.

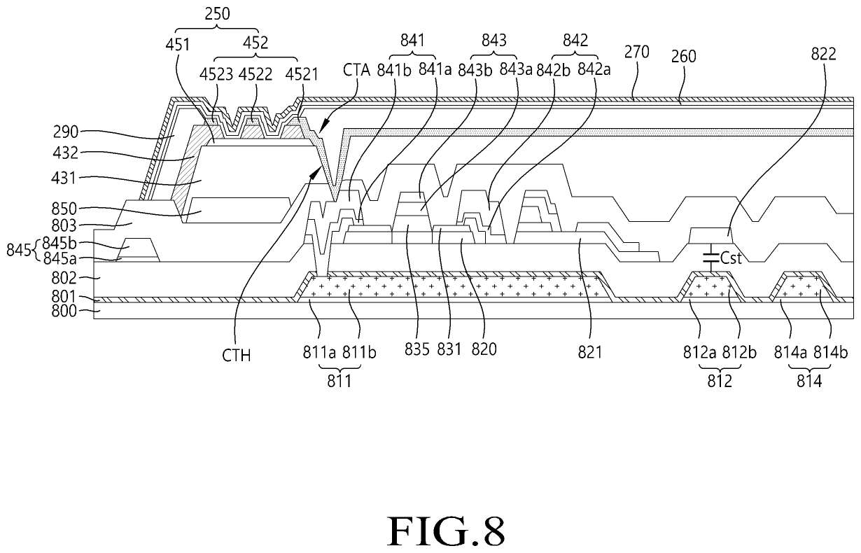

FIG. 8 is a cross-sectional view schematically illustrating an example structure of the display device 100 according to aspects of the present disclosure.

Referring to FIG. 8, in one or more embodiments, the display panel 100 may include at least one thin film transistor and at least one light emitting element disposed over substrate 800.

In one or more embodiments, a plurality of signal lines (811 and 814) and a light shield 812 may be disposed on the substrate 800. Each of the signal lines (811 and 814) of FIG. 8 may be any one of the plurality of signal lines (201 and 202) illustrated in FIG. 3.

Each of the signal lines (811 and 814) may include multiple layers.

For example, the signal line 811 may include a first layer 811a and a second layer 811b disposed on the first layer 811a, and the signal line 814 may include a fifth layer 814a and a sixth layer 814b disposed on the fifth layer 814a. The light shield 812 may also include multiple layers. For example, the light shield 812 may include a third layer 812a and a fourth layer 812b disposed on the third layer 812a.

The first layer 811a, the third layer 812a, and the fifth layer 814a may include the same material, and the second layer 811b, the fourth layer 812b, and the sixth layer 814b may include the same material.

A first insulating layer 801 and a second insulating layer 802 may be disposed on the plurality of signal lines (811 and 814) and the light shield 812.

A thin film transistor and a plurality of electrodes may be disposed on the second insulating layer 802.

For example, referring to FIG. 8, a first active layer 820, a second active layer 821, and a third active layer 822 may be disposed on the second insulating layer 802 in the active area of the display panel.

At least one of the first to third active layers (820, 821, and 822) may include an oxide semiconductor material. The oxide semiconductor material may be a semiconductor material obtained by controlling conductivity and adjusting a band gap through doping in an oxide material, and may be a transparent semiconductor material having a relatively wide band gap. For example, the oxide semiconductor material may include indium gallium zinc oxide (IGZO), Zinc oxide (ZnO), indium gallium oxide (IGO), indium zinc oxide (IZO), cadmium oxide (CdO), indium oxide (InO), zinc tin oxide (ZTO), zinc indium tin oxide (ZITO), indium gallium zinc tin oxide (IGZTO), and the like.

A gate insulating layer 835 may be disposed on the first active layer 820 and the second active layer 821.

Each of the first to third active layers (820, 821, and 822) may be in a conductivity-enabled state in areas not overlapping with the gate insulating layer 835. For examples, respective portions of the first to third active layers (820, 821, and 822) not overlapping with the gate insulating layer 835 may be conductive portions.

Referring to FIG. 8, the third active layer 822 may become conductive and serve as an electrode, and the third active layer 822 may form a storage capacitor Cst with a signal line 812 disposed under the third active layer 822.

Referring to FIG. 8, the gate insulating layer 835 may be disposed on a portion of the upper surface of the first active layer 820 and a portion of the upper surface of the second active layer 821.

The first active layer 820 may include auxiliary electrodes 831. Auxiliary electrodes 831 may be disposed in conductive portions of the first active layer 820. The auxiliary electrodes 831 may electrically connect conductive portions of the first active layer 820 and a source electrode 841 and a drain electrode 842.

In the active area, a source electrode 841, a drain electrode 842, and a gate electrode 843 may be disposed on the gate insulating layer 835. FIG. 8 illustrates an example where an electrode 841 is the source electrode and an electrode 842 is the drain electrode, but aspects of the present disclosure are not limited thereto. For example, the electrode 841 may be the drain electrode and the electrode 842 may be the source electrode.

In one or more aspects, in the non-active area of the display panel 110, the source electrode 841, the drain electrode 842, and the gate electrode 843 may be disposed in the same layer and may include the same material. In one or more aspects, as illustrated in FIG. 8, a pad electrode 845 may be disposed on the second insulating layer 802.

For example, the source electrode 841, the drain electrode 842, the gate electrode 843, and the pad electrode 845 may include multiple layers.

For example, each of the source electrode 841, the drain electrode 842, the gate electrode 843, and the pad electrode 845 may include two or more layers, but aspects of the present disclosure are not limited thereto. For example, at least one of the source electrode 841, the drain electrode 842, the gate electrode 843, and the pad electrode 845 may be a single layer.

A first layer 841a of the source electrode 841, a first layer 842a of the drain electrode 842, a first layer 843a of the gate electrode 843, and a first layer 845a of the pad electrode 845 may include the same material, and a second layer 841b of the source electrode 841, a second layer 842b of the drain electrode 842, a second layer 843b of the gate electrode 843, and a second layer 845b of the pad electrode 845 may include the same material. However, aspects of the present disclosure are not limited thereto. For example, the first layer 841a of the source electrode 841, the first layer 842a of the drain electrode 842, the first layer 843a of the gate electrode 843, and the first layer 845a of the pad electrode 845 may include different materials, and the second layer 841b of the source electrode 841, the second layer 842b of the drain electrode 842, the second layer 843b of the gate electrode 843, and the second layer 845b of the pad electrode 845 may include different materials.

A third insulating layer 803 may be disposed over the substrate 800 over which the source electrode 841, the drain electrode 842, and the gate electrode 842 are disposed in an active area.

A color filter 850 may be disposed on the third insulating layer 803. The color filter 850 may overlap with a plurality of light emitting areas formed in one subpixel.

A first planarization layer 431 may be disposed on the color filter 850.

The first planarization layer 431 may include a hole for allowing a light emitting element and a thin film transistor to be electrically interconnected. The hole of the first planarization layer 431 may overlap with a hole in the third insulating layer 803 to form a contact hole CTH.

A first pixel electrode 451 may be disposed on the first planarization layer 431.

A second planarization layer 432 may be disposed on the first planarization layer 431 and the first pixel electrode 451.

The second planarization layer 432 may include at least one opened portion in one subpixel.

The at least one opened portion may include a lower surface and an inclined surface extending along a side surface of the second planarization layer 432 from the lower surface. The second planarization layer 432 may include an upper surface extending from the side surface or the inclined surface.

The first pixel electrode 451 may be exposed on the lower surface of the at least one opened portion.

For example, referring to FIG. 8, the at least one opened portion of the second planarization layer 432 may overlap with a portion of the color filter 850. However, aspects of the present disclosure are not limited thereto. For example, the at least one opened portion of the second planarization layer 432 may be disposed even in a subpixel where the color filter 850 is not disposed.

Referring to FIG. 8, the side surface of the second planarization layer 432 may be located adjacent to the hole in the first planarization layer 431, and be disposed such that the first pixel electrode 451 cannot be covered by the side surface of the second planarization layer 432.

A second pixel electrode 452 may be disposed on the second planarization layer 432. In one or more aspects, in the cross-sectional view, the second pixel electrode 452 may include a plurality of second pixel electrode portions (4521, 4522, and 4523) spaced apart from each other. In this configuration, a corresponding one of opened portions formed in the second planarization layer 432 may be located between adjacent second pixel electrode portions among the second pixel electrode portions (4521, 4522, and 4523). The second pixel electrode 452 may be configured to extend to a portion of the first planarization layer 431 disposed in a circuit area, which is a non-light emitting area NDA.

Referring to FIG. 8, the first pixel electrode 451 and the second pixel electrode 452 may be electrically connected at a contact area CTA on a side surface of the second planarization layer 432. For example, one portion 4521 of the second pixel electrode 452 and one end or edge of the first pixel electrode 451 may be electrically connected at the contact area CTA.

Referring to FIG. 8, the second pixel electrode 452 may be electrically connected to the source electrode 841 of the thin film transistor through the contact hole CTH. For example, as one portion 4521 of the second pixel electrode 452 is electrically connected to the thin film transistor, a pixel electrode 250 including the first pixel electrode 451 and the second pixel electrode 452 can be electrically connected to the thin film transistor.

As shown in FIGS. 6A to 6E, at least one opened portion CON may be disposed in one subpixel. The second pixel electrode 452 may have a structure where at least one hole is formed in at least one portion of the second pixel electrode 452 corresponding to the at least one opened portion CON. For example, the at least one hole formed in the second pixel electrode 452 may correspond to at least one portion of the first pixel electrode 451 where the first pixel electrode 451 is exposed.

Referring to FIG. 8, a bank 290 may be disposed over the substrate 800 over which the second pixel electrode 452 is disposed.

For example, the bank 290 may include at least one opening OP in one subpixel.

A plurality of opened portions may be disposed in the opening OP of the bank 290. In one or more embodiments, a plurality of light emitting areas may be formed in the opening OP of the bank 290.

For example, a first light emitting area and a second light emitting area formed respectively on the lower surface and the inclined surface of an opened portion, and a third light emitting area formed on the upper surface of the second planarization layer 432 may be formed in the opening OP.

Referring to FIG. 8, an emission layer 260 and a common electrode 270 of a light emitting element may be sequentially disposed over the substrate 800 over which the bank 290 is disposed.

For example, the first pixel electrode 451, the emission layer 260, and the common electrode 270 may be disposed on the lower surface of an opened portion. The emission layer 260 and the common electrode 270 may be disposed on the inclined surface of the opened portion. The second pixel electrode 452, the emission layer 260, and the common electrode 270 may be disposed on the upper surface of the second planarization layer 432.

As the common electrode 270 including a reflective electrode is disposed on the inclined surface, light emitted from the emission layer 260 disposed between the second pixel electrode 452 and the common electrode 270 can be reflected by the inclined surface of the common electrode 270, and thereafter, be directed outside of the substrate 800.

According to the embodiments described herein, a display device can be provided that is capable of eliminating or reducing display artifacts such as stained image presenting and the like and improving light emission efficiency.

According to the embodiments described herein, a display device may be provided that is capable of producing improved light emission efficiency based on a structure where one subpixel includes a double-layered pixel electrode.

According to the embodiments described herein, a display device may be provided that is capable of eliminating or reducing display artifacts such as stained image presenting and the like based on a structure where one subpixel includes a double-layered pixel electrode.

According to the embodiments described herein, a display device may be provided that is capable of being driven with low power through high luminance characteristics based on a structure where one subpixel includes a plurality of light emitting areas emitting light of the same color.

The example embodiments described above will be briefly described as follows.

According to the example embodiments described herein, a display device can be provided that includes a substrate on which a plurality of subpixels are disposed, each of the plurality of subpixels including a plurality of light emitting areas, a first planarization layer disposed over the substrate, a first pixel electrode disposed on the first planarization layer, a second planarization layer disposed on the first pixel electrode, and the second planarization layer including at least one opened portion exposing at least a portion of the upper surface of the first pixel electrode, a second pixel electrode disposed on the second planarization layer, a bank disposed on a portion of the upper surface of the second pixel electrode, and the bank including an opening in each of the plurality of subpixels, an emission layer disposed in the opening, and a common electrode disposed on the emission layer.

In one or more embodiments, the at least one opened portion may be disposed in each of the plurality of subpixels.

In one or more embodiments, the first pixel electrode and the second pixel electrode may not overlap with each other in the at least one opened portion.

In one or more embodiments, the second pixel electrode may include at least one hole disposed in at least one area corresponding to the at least one opened portion.

In one or more embodiments, each of the plurality of subpixels may include a circuit area, and a contact area in which the first pixel electrode and the second pixel electrode are electrically connected may be disposed in the circuit area.

In one or more embodiments, each of the plurality of subpixels may include a transistor, and the second pixel electrode may be electrically connected to the transistor.

In one or more embodiments, the at least one opened portion may include a lower surface and an inclined surface extending along a side surface of the second planarization layer from the lower surface, and the second planarization layer may include an upper surface extending from the inclined surface.

In one or more embodiments, the first pixel electrode, the emission layer, and the common electrode may be configured to be stacked in an area corresponding to the lower surface.

In one or more embodiments, the emission layer and the common electrode may be configured to be stacked in an area corresponding to the inclined surface.

In one or more embodiments, the second pixel electrode, the emission layer, and the common electrode may be configured to be stacked in an area corresponding to the upper surface of the second planarization layer.

In one or more embodiments, the common electrode may include a reflective material.

In one or more embodiments, the plurality of light emitting areas may include a first light emitting area disposed in an area corresponding to the lower surface.

In one or more embodiments, the plurality of light emitting areas may include a second light emitting area disposed in an area corresponding to the inclined surface.

In one or more embodiments, the plurality of light emitting areas may include a third light emitting area disposed in an area corresponding to the upper surface of the second planarization layer.

In one or more embodiments, the second light emitting area may be configured to surround the first light emitting area.

In one or more embodiments, the third light emitting area may be configured to surround the second light emitting area.

In one or more embodiments, the display device may further include a color filter disposed between the substrate and the first planarization layer, and the at least one opened portion may overlap with a portion of the color filter.

According to the example embodiments described herein, a display device can be provided that includes a plurality of light emitting areas disposed in one subpixel, the plurality of light emitting areas including at least one first light emitting area disposed in the one subpixel, a second light emitting area surrounding the at least one first light emitting area, and a third light emitting area surrounding the second light emitting area, and includes at least one opened portions located in the one subpixel, the at least one opened portion allowing the at least one first light emitting area and the second light emitting area being disposed in the opened portions.

In one or more embodiments, the opened portions may be spaced apart from each other in the one subpixel and be arranged in a polygonal shape.

In one or more embodiments, the opened portions may be spaced apart from each other in a column direction or row direction in the one subpixel.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a substrate on which a plurality of subpixels are disposed, each of the plurality of subpixels comprising a plurality of light emitting areas;
a first planarization layer over the substrate;
a first pixel electrode on the first planarization layer;
a second planarization layer on the first pixel electrode, the second planarization layer comprising at least one opened portion exposing at least a portion of an upper surface of the first pixel electrode;
a second pixel electrode on the second planarization layer;
a bank on a portion of an upper surface of the second pixel electrode, the bank comprising an opening in each of the plurality of subpixels;
an emission layer in the opening; and
a common electrode on the emission layer.

2. The display device of claim 1, wherein the at least one opened portion is in each of the plurality of subpixels.

3. The display device of claim 1, wherein the first pixel electrode and the second pixel electrode are non-overlapping with each other in the at least one opened portion.

4. The display device of claim 1, wherein the second pixel electrode comprises at least one hole in at least one area corresponding to the at least one opened portion.

5. The display device of claim 1, wherein each of the plurality of subpixels comprises a circuit area and a contact area in which the first pixel electrode and the second pixel electrode are electrically connected is disposed in the circuit area.

6. The display device of claim 5, wherein each of the plurality of subpixels comprises a transistor and the second pixel electrode is electrically connected to the transistor.

7. The display device of claim 1, wherein the at least one opened portion comprises a lower surface and an inclined surface extending along a side surface of the second planarization layer from the lower surface, and the second planarization layer comprises an upper surface extending from the inclined surface.

8. The display device of claim 7, wherein the first pixel electrode, the emission layer, and the common electrode are stacked in an area corresponding to the lower surface.

9. The display device of claim 7, wherein the emission layer and the common electrode are stacked in an area corresponding to the inclined surface.

10. The display device of claim 7, wherein the second pixel electrode, the emission layer, and the common electrode are stacked in an area corresponding to the upper surface.

11. The display device of claim 1, wherein the common electrode comprises a reflective material.

12. The display device of claim 7, wherein the plurality of light emitting areas comprise a first light emitting area in an area corresponding to the lower surface.

13. The display device of claim 12, wherein the plurality of light emitting areas comprise a second light emitting area in an area corresponding to the inclined surface.

14. The display device of claim 13, wherein the plurality of light emitting areas comprise a third light emitting area in an area corresponding to the upper surface.

15. The display device of claim 14, wherein the second light emitting area surrounds the first light emitting area.

16. The display device of claim 15, wherein the third light emitting area surrounds the second light emitting area.

17. The display device of claim 1, further comprising:
a color filter between the substrate and the first planarization layer,
wherein the at least one opened portion overlaps with a portion of the color filter.

18. A display device comprising:
a plurality of light emitting areas in one subpixel, the plurality of light emitting areas comprising:
at least one first light emitting area in the one subpixel;
a second light emitting area surrounding the at least one first light emitting area; and
a third light emitting area surrounding the second light emitting area; and
at least one opened portion in the one subpixel, the at least one opened portion allowing the at least one first light emitting area and the second light emitting area to be disposed.

19. The display device of claim 18, wherein two or more opened portions included in the at least one opened portion are spaced apart from each other in the one subpixel and are arranged in a polygonal shape.

20. The display device of claim 18, wherein two or more opened portions included in the at least one opened portion are spaced apart from each other in a column direction or row direction in the one subpixel.
